(19) United States
(12) Patent Application Publication
(10) Pub. No.: US 2013/0313693 A1
(43) Pub. Date: Nov. 28, 2013

(54) EPOXY-THIOL COMPOSITIONS WITH IMPROVED STABILITY

(71) Applicant: Henkel Ireland Limited, (US)

(72) Inventors: Barry N. Burns, Dublin (IE); Jonathan P. Wigham, Rathfarnham (IE)

(73) Assignee: Henkel Ireland Limited, Monheim (DE)

(21) Appl. No.: 13/770,234

(22) Filed: Feb. 19, 2013

Related U.S. Application Data
(63) Continuation of application No. PCT/EP2011/069366, filed on Nov. 3, 2011.
(60) Provisional application No. 61/410,561, filed on Nov. 5, 2010.

(51) Int. Cl. C09J 163/00; H01L 23/00

(52) U.S. Cl. CPC C09J 163/00; H01L 24/83; H01L 24/31
USPC 257/666; 523/400; 438/118

(57) ABSTRACT

A curable one-part epoxy resin composition is described. The composition comprises an epoxy component comprising at least one epoxy compound which has two or more groups per molecule; a latent hardener component; a thixotropy-conferrring component; a polythiol component comprising a polythiol having at least one secondary or tertiary thiol group per molecule; and a stabilising component comprising a solid organic acid. The compositions according to the invention are particularly suitable for use in the field of microelectronics.

### FIELD

This invention relates to curable one-part epoxy based compositions. In particular the invention relates to curable epoxy-thiol compositions having improved performance and improved shelf-life stability.

### BACKGROUND

Curable epoxy-based compositions are well known. Such compositions are used as adhesives, coating agents, sealing agents and may also be used as casting agents. Epoxy-based compositions are also used in the electronics industry for the fabrication of heat resistant printed circuit laminates for printed circuit boards (pcbs). One use of curable epoxy compositions is to bond surface mount components to pcbs.

Epoxy/polythiol-containing compositions conventionally have been used as two-part compositions. This was due at least in part to the instability of a one-part composition, having an epoxy resin and a polythiol component and a liquid (soluble) tertiary amine curing agent or hardener. One-part compositions of this sort where the epoxy resin-polythiol and the curing agent or hardener were admixed at room temperature had working or “pot” lives on the order of minutes to a few hours. Such short “pot lives” are undesirable as they impose practical restrictions on end-use applications of such compositions. Accordingly, many traditional epoxy/polythiol compositions have been formulated as two-part compositions.

Commercially available latent curing agents used in one-part epoxy resin adhesive formulations ordinarily provide such formulations with a combination of good storage stability and moderate reactivity at elevated temperatures. Examples of such commercially available latent curing agents include dicyandiamide and dibasic acid dihydrazide. These curing agents are useful in formulating epoxy resin compositions with excellent storage stability. However to achieve cure, these curing agents ordinarily require heating to temperatures greater than 150° C. for extended periods of time.

U.S. Pat. No. 5,430,112 (Sakata) discloses epoxy resin/polythiol compositions which are reported to display enhanced stability, i.e. an extended pot life, if (a) a solid dispersion-type amine adduct latent curing accelerator, or (b) the product of a reaction between a compound which contains one or more isocyanate groups in its molecule and a compound which has two or more primary and/or secondary amino groups in its molecule, is used. The compounds (a) and (b) above are each reported to act as a “latent hardener”, being activatable at higher temperatures. In particular, the composition disclosed in the '112 patent contains (1) an epoxy resin which has two or more epoxy groups in its molecule, (2) a polythiol compound which has two or more thiol groups in its molecule and (3) an accelerator which is (a) a solid dispersion-type amine adduct latent curing accelerator, or (b) the product of a reaction between a compound which contains one or more isocyanate groups in its molecule and a compound which has at least one primary and/or secondary amino groups in its molecule. Examples given of commercially available solid dispersion-type amine adduct latent curing accelerators are those sold under the trade names Ajicure PN-H or Ajicure PN-23 (commercially available from Ajinomoto Co., Inc., Tokyo, Japan). The compositions containing these amine adduct latent curing accelerators show improved room temperature stability over conventional formulations based on liquid or soluble tertiary amine curing agents. However, in practice such compositions with a pot life of in excess of 1 week at room temperature, show a poor ability to cure, i.e. their ability to cure in less than 30 mins at 80° C. is poor.

The stability of an epoxy resin/polythiol composition of the '112 patent is reported to be improved by the use of a solid dispersion-type amine adduct latent curing accelerator and/or the product of a reaction between an isocyanate and an amine containing group, though compositions containing Ajicure PN-23 are not described. However, improved stability, for at least the commercially available Ajicure PN-H, is achieved at the expense of gel time, i.e. greater stability is achieved only with an undesirable effect of increase in gel time.

The '112 patent also describes the use of liquid or solid organic or inorganic acids for surface treating the latent hardener (the amine adduct) and for use in making the latent hardener. The treatment of the hardener with an acid is designed to neutralise active basic materials on the surface of the hardener particles as the hardener is ordinarily in a solid state. The organic or inorganic acid is often in a liquid state or in a solution to allow for the surface treatment, or for making the latent hardener.

An English-language abstract (produced by Derwent) (accession no. 86-229126) for Japanese laid-open patent application no. S61-159417 (Japanese Patent No. 92014701) discloses a two-part curable epoxy resin composition containing, epoxy compounds having on average above one epoxy group in one molecule, thiol compounds containing about one thiol group in one molecule as a hardener (though not a latent one), amines as a curing accelerator and mercapto-organic acids containing one carboxylic group and one thio group in one molecule as a curing retarder.

U.S. Pat. No. 6,872,762 describes epoxy/polythiol compositions comprising (a) an epoxy compound which has two or more epoxy groups per molecule, (b) a polythiol compound which has two or more thiol groups per molecule, (c) a latent hardener, and (d) at least one solid organic acid which is substantially insoluble in a mixture of (a), (b) and (c) above, at room temperature. The composition described is used to bond surface mount devices to the surface of a PCB.

Notwithstanding state-of-the-art compositions, there is a need for an improved, more user-friendly epoxy/polythiol composition. In particular, there is a need for improved epoxy-polythiol adhesive compositions having improved thermal stability, such as improved room temperature pot life and with extended working lives. It would be desirable to provide compositions with improved rheological properties such as improved shelf-life stability, particularly with respect to yield point maintenance over time, viscosity maintenance over time, in addition to storage stability. It would be particularly desirable to provide compositions having an improved pot life.

The present invention seeks to provide improved curable one-part epoxy-polythiol compositions with improved performance in terms of thermal stability, glass transition temperature (“Tg”) and hydrolytic stability and, in particular, improved pot life compared to known compositions.

### SUMMARY

The invention provides a curable one-part epoxy resin composition, comprising:
(a) an epoxy component comprising at least one epoxy compound which has two or more groups per molecule;
(b) a latent hardener component;
(c) a thixotropy-conferrring component;
(d) a polythiol component comprising a polythiol having at least one secondary or tertiary thiol group per molecule; and
(e) a stabilising component comprising a solid organic acid.

The inventors have determined that, surprisingly, the compositions according to the invention comprising a polythiol having at least one secondary or tertiary thiol group demonstrate improved pot life compared to compositions comprising a polythiol having solely at least one primary thiol group. The polythiols used in accordance with the invention are multifunctional thiol materials and are desirably those with at least one secondary or tertiary mercaptan group. It is thought that the mercaptan group may be capable of internal hydrogen bonding for example to a β-positioned carbonyl group. The polythiols used in accordance with the invention may comprise at least one primary thiol group, at least one secondary thiol group and at least one tertiary thiol group or various combinations thereof.

Suitably the polythiol comprises at least two secondary thiol groups per molecule.

The polythiol may comprise at least three secondary thiol groups per molecule.

The polythiol may comprise at least four secondary thiol groups per molecule.

Polythiols suitable for use in accordance with the present invention may be synthesised according to procedures known to those skilled in the art. The polythiols used in the invention are polyfunctional thiols.

The skilled person will appreciate that monofunctional secondary thiols can be used to produce polyfunctional secondary thiols suitable for use in the present invention. For example, hydroxy functional secondary thiol materials such as 1-mercaptoethanol, 2-mercapto-1-propanol, 3-mercapto-1-butanol or 4-mercapto-1-pentanol and carboxylic acid functional secondary thiols such as 2-mercaptopropanoic acid, 3-mercaptobutanoic acid or 4-mercaptopentanoic acid may be converted into higher polyfunctional secondary thiol materials via esterification procedures.

Polyfunctional tertiary thiol materials may be prepared using procedures known from the literature. For example, Fokin et al., Organic Letters 2006 Vol. 8 No. 9 pp1767-1770 details the preparation of a tetramantane difunctional tertiary thiol. Other procedures for the preparation of tertiary thiols may be found in Tetrahedron Vol. 62 (35) pp8410-8418 (2006), Mukaiyama et al., Chemistry Letters Vol. 30 (2001) No. 7 p6.38 which details the synthesis of 2⁰/3⁰ thiols from olefins using thiocarbonate, titanium (iv) chloride/fluoride and copper (ii) oxide. It is known in the prior art that tertiary thiols can be prepared by Markovnikov addition of hydrogen sulphide to a substituted olefin. For example U.S. Pat. No. 5,453,544 describes the preparation of tertiary thiols by reacting hydrogen sulphide with C3 to C15 olefins in the presence of a microporous crystalline catalyst.

The polythiol may be selected from

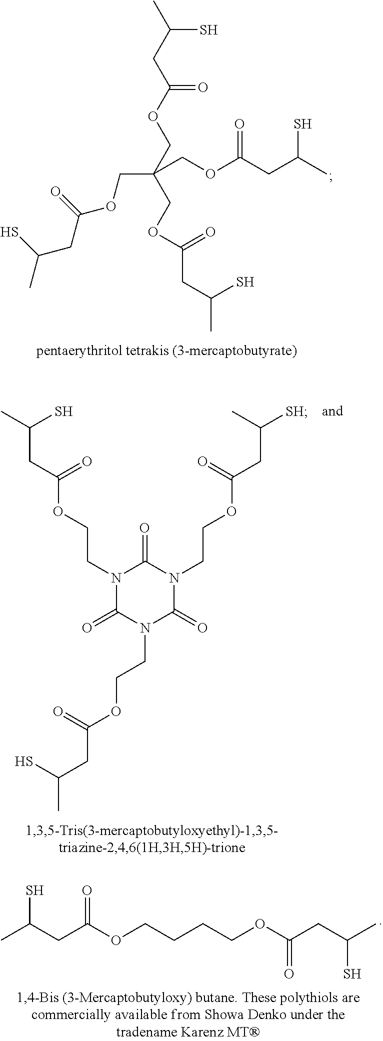

The composition according to the invention is suitable for use as an adhesive to mount electronic components.

In one aspect the invention provides a composition comprising:

(a) about 100 parts of an epoxy component comprising at least one epoxy compound;

(b) about 5 to 45 parts of a latent hardener component;

(c) about 5 to 40 parts of a thixotropy-conferring component; and

(d) about 20 to 200 parts of a secondary polythiol; and

(e) about 0.1 to 25 parts of a solid organic acid.

In another aspect the invention provides a composition comprising:

(a) about 100 parts of an epoxy component comprising at least one epoxy compound;

(b) about 10-30 parts of a latent hardener component;

(c) about 5-15 parts of a thixotropy-conferring component; and

(d) about 20 to 200 parts of a secondary polythiol; and optionally

(e) about 0.1 to 25 parts of a solid organic acid.

It will be appreciated that the amounts of latent hardener and secondary or tertiary polythiol used depends on the epoxide equivalent weight of the particular epoxy resin used.

The composition according to the invention may have a Tₒₙₛₑₜ in the range of 40-120° C., more particularly in range 50-100° C.

The Tₒₙₛₑₜ temperatures of the compositions described herein are relatively high compared to those of the known compositions comprising solely at least one polythiol having a primary thiol group. A high Tₒₙₛₑₜ temperature can improve the thermal stability of the composition.

Suitably, the composition according to the invention has a viscosity in the range of 0.5-100 Pa·s.

Suitably, the composition according to the invention has a yield point in the range 30-1000 Pa. The formulations according to the invention demonstrate a vastly improved pot life when compared to the equivalent compositions comprising primary polythiols.

The invention also provides a process for preparing a curable one-part epoxy resin composition, comprising the steps of: combining initially (i) an epoxy component and a polythiol having at least one secondary or tertiary thiol group per molecule; (ii) adding a solid organic acid and one or more excipients and shearing under vacuum; (iii) allowing said mixture to cool; and (iv) adding a latent hardener and mixing under vacuum for a time sufficient to form the curable one-part epoxy composition.

The term ‘epoxy resin compositions of the present invention’ as used herein refers to compositions of the invention and includes such compositions having one or more further components.

The present invention also provides reaction products of the epoxy resin compositions, which exhibit good adhesive strengths when cured.

The epoxy resin compositions of the present invention are appropriate for use in any conventional application of epoxy compositions, such as adhesive or coating agents.

The invention also provides a method of using such epoxy-resin compositions in the manufacture of electronic mounting structures, as for instance surface mount adhesives.

They may be used in the electronics industry generally, including the microelectronic industry. One commercial use of epoxy resins is to bond a surface mount semiconductor device to a pcb in a chip bonding application. A method of using a composition of the invention to achieve such a result typically includes the steps of: (i) dispensing onto an appropriate location on a carrier substrate a sufficient amount of the composition, (ii) positioning over the location bearing the composition an electronic component, (iii) mating the electronic component with the carrier substrate, and (iv) exposing the mated electronic component/carrier substrate assembly to conditions favourable to effect cure of the composition.

Another commercial use is as an underfill sealant to seal the space between a semiconductor device electrically connected to a circuit board. The epoxy resin compositions of the invention are suitable for this purpose.

The epoxy resin compositions of the present invention may be used as an underfilling sealing resin. In this application, the compositions enable a semiconductor device, such as a chip scale package/ball grid array (CSP/BGA) assembly, which includes a semiconductor chip mounted on a carrier substrate, to be securely connected to a circuit board by short-time heat curing.

A method of underfilling a space between an electronic component and a carrier substrate the electronic component being mounted on the carrier substrate typically includes the step of dispensing an amount of an epoxy resin composition according to the present invention into the space between the electronic component and the carrier substrate, and exposing the epoxy resin composition to conditions which effect cure, is also provided.

Thus the invention further provides an electronic device comprising a semiconductor device and a circuit board to which said semiconductor device is electrically connected, assembled using an epoxy resin composition according to the invention to mount the semiconductor to the circuit board.

In use, the epoxy resin compositions of the present invention may be applied to a substrate in any conventional fashion. Suitable application modes include syringe dispensing, pin-transfer, screen-printing, and through other conventional adhesive dispensing equipment.

The present invention will be more fully understood by a reading of the Detailed Description of the Invention, together with the FIGURE which follows.

### BRIEF DESCRIPTION OF THE DRAWINGS

FIG. 1 shows viscosity stability at 40° C. for control+formulations I-IV from Table 4.

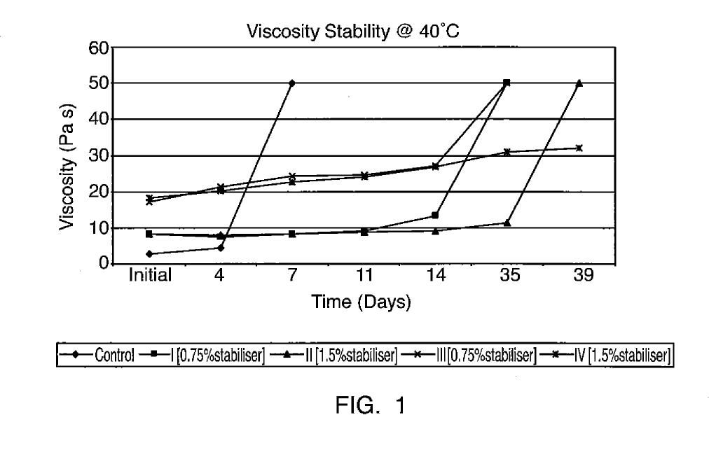

### DETAILED DESCRIPTION

Discussion of the Epoxy Resin Component:

This invention relates to curable epoxy-based compositions such as those having an epoxy compound which has two or more epoxy groups. The epoxy compound for the epoxy resin compositions of the present invention may be selected from any polymeric epoxide which has an average of two or more epoxide groups per molecule, including polyglycidyl ethers of polyhydric phenols, for example, polyglycidyl ethers of bisphenol A, bisphenol F, bisphenol AD, catechol, resorcinol. Epoxy compounds obtained by reacting polyhydric alcohols such as butinediol or polyethylene glycol or glycerin with epichlorohydrin, are also suitable. Epoxidised (poly)olefinic resins, epoxidised phenolic novolac resins, epoxidised cresol novolac resins and cycloaliphatic epoxy resins may also be used. Also included are glycidyl ether esters, such as those obtained by reacting hydroxycarboxylic acid with epichlorohydrin, and polyglycidyl esters, such as those obtained by reacting a polycarboxylic acid with epichlorohydrin. Urethane modified epoxy resins are also suitable. Other suitable epoxy compounds include polyepoxy compounds based on aromatic amines and epichlorohydrin, such as N,N′-diglycidyl-aniline; N,N′-dimethyl-N,N′-diglycidyl-4,4′ diaminodiphenyl methane; N,N,N′,N′-tetraglycidyl-4,4′ diaminodiphenyl methane; N-diglycidyl-4-aminophenyl glycidyl ether; and N,N,N′,N′-tetraglycidyl-1,3-propylene bis-4-aminobenzoate. Combinations of these epoxy compounds may be used. Among the epoxy resins suitable for use herein are polyglycidyl derivatives of phenolic compounds, such as those available commercially under the trade names EPON 828, EPON 1001, EPON 1009, and EPON 1031, from Shell Chemical Co.; DER 331, DER 332, DER 334, and DER 542 from Dow Chemical Co.: and BREN-S from Nippon Kayaku, Japan. Other suitable epoxy resins include polyepoxides prepared from polyols and the like and polyglycidyl derivatives of phenol-formaldehyde novolacs, the latter of which are available commercially under the trade names DEN 431, DEN 438, and DEN 439 from Dow Chemical Company. Cresol analogs are also available commercially ECN 1235, ECH 1273, and ECN 1299 from Ciba-Geigy Corporation. SU-8 is a bisphenol A-type epoxy novolac available from Interez, Inc. Polyglycidyl adducts of amines, aminoalcohols and polycarboxylic acids are also useful in this invention, commercially available resins of which include GLYAMINE 135, GLYAMINE 125, and GLYAMINE 115 from F.I.C. Corporation; ARALDITE MY-720, ARALDITE 0500, and ARALDITE 0510 from Ciba-Geigy Corporation and PGA-X and PGA-C from the Sherwin-Williams Co. Epoxy resins are discussed in U.S. Pat. No. 5,430,112 the entire contents of which are hereby incorporated herein.

Within the epoxy component may be included appropriate reactive diluents which include monofunctional or certain multifunctional epoxy resins. The reactive diluent should have a viscosity which is lower than that of the epoxy compounds within the epoxy component having at least two epoxy groups. Ordinarily, the reactive diluent should have a viscosity less than about 250 mPa·s (cPs). In the event such a monofunctional epoxy resin is included within the epoxy component as a reactive diluent, such mono-functional epoxy resin should be employed in an amount of up to about 50 parts based on the total of the epoxy resin component.

The monofunctional epoxy resin should have an epoxy group with an alkyl group of about 6 to about 28 carbon atoms, examples of which include C₆-C₂₈ alkyl glycidyl ethers, C₆-C₂₈ fatty acid glycidyl esters and C₆-C₂₈ alkylphenol glycidyl ethers.

Commercially available monofunctional epoxy resin reactive diluents include those from Pacific Epoxy Polymers, Richmond, Miss., under the trade designations PEP-6770 (glycidyl ester of neodecandoic acid), PEP-6740 (phenyl glycidyl ether) and PEP-6741 (butyl glycidyl ether).

Commercially available reactive diluents include those from Pacific Epoxy Polymers, under the trade designations PEP-6752 (trimethylolpropane triglycidyl ether) and PEP-6760 (diglycidyl aniline).

Suitably the epoxy resin is present in amounts of about 20 to about 80% based on the total weight of the composition, such as about 45 to about 70%.

Discussion of the Polythiol Component:

The polythiol compound for compositions according to the invention may be selected from any mercapto compound which has one or more secondary thiol groups per molecule, such as pentaerythritol tetrakis (3-mercaptobutyrate), 1,3,5-Tris(3-mercaptobutyloxyethyl)-1,3,5-triazine-2,4,6(1H,3H,5H)-trione or 1,4-Bis (3-Mercaptobutyloxy) butane for example.

Alternatively, the polythiol compound may be selected from any mercapto compound which has one or more tertiary thiol groups per molecule.

Polythiols may be added in amounts of about 25 to about 50% based on the total weight of the composition, such as about 33 to about 40%.

Suitably the ratio of the epoxy compound to polythiol compound in the composition is such that the ratio of epoxy equivalents to thiol equivalents is about 0.5:1 to about 1.5:1, such as about 0.75:1 to about 1.3:1.

The polythiol compounds used in accordance with the present invention are multifunctional polythiol materials. The secondary thiol group is capable of internal hydrogen bonding to a β-positioned carbonyl group. In general, secondary thiols are less reactive compared to primary thiols due mainly to steric and inductive effects associated with the presence of adjoining methyl groups.

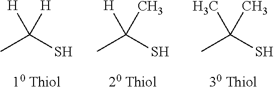

This reduced reactivity results in reduced incidence of formation of thiolate anions which are responsible for initiating slow rates of polymerisation at room temperature leading to increases in viscosity/decrease in yield point. The use of a slightly less reactive thiol therefore helps to stabilise the viscosity/yield point of a formulation and hence improve shelf life/sensitivity to temperature fluctuations under normal storage conditions.

Discussion of the Latent Hardener Component:

The epoxy resin compositions of the present invention include at least one latent hardener, which typically is heat activatable. Such a latent hardener should be substantially inactive at room temperature but be capable of activation at temperatures above 50[deg.] C to effect the heat cure of the epoxy resin. Suitable hardeners are described in British Patent 1,121,196 (Ciba Geigy AG), European Patent Application 138465A (Ajinomoto Co.) or European Patent Application 193068A (Asahi Chemical), the disclosure of each of which are hereby expressly incorporated herein by reference. Other suitable hardeners for use herein include commercially available ones, such as Anchor Chemical 2014. British Patent 1,121,196 describes a reaction product of phthalic anhydride and an aliphatic polyamine, more particularly a reaction product of approximately equimolar proportions of phthalic acid and diethylamine triamine. A hardener of this type is available commercially from Ciba Geigy AG under the trade mark CIBA HT 9506.

Yet another type of latent hardener is a reaction product of (i) a polyfunctional epoxy compound, (ii) an imidazole compound such as 2-ethyl-4-methylimidazole and (iii) phthalic anhydride. The polyfunctional epoxy compound may be any compound having two or more epoxy groups in the molecule as described in U.S. Pat. No. 4,546,155, the disclosure of which is hereby expressly incorporated herein by reference. A hardener of this type is commercially available from Ajinomoto Co. Inc. under the trade mark AJICURE PN-23, is believed to be an adduct of EPON 828 (bisphenol type epoxy resin epoxy equivalent 184-194, commercially available from Shell Chemical Co.), 2-ethyl-4-methylimidazole and phthalic anhydride.

Other suitable hardeners are those given in U.S. Pat. No. 5,077,376, and those of the '112 patent termed “amine adduct latent accelerators”, or the reaction product of a compound having one or more isocyanate groups in its molecule with a compound having at least one primary or secondary amino group in its molecule.

Additional latent hardeners include 2-heptadeoylimidazole, 2-phenyl-4,5-dihydroxymethylimidazole, 2-phenyl-4-methyl-5-hydroxymethylimidazole, 2-phenyl-4-benzyl-5-hydroxymethylimidazole, 2,4-diamino-8-2-methylimidazolyl-(1)-ethyl-5-triazine, additional products of triazine with isocyanuric acid, succinohydrazide, adipohydrazide, isophtholohydrazide, o-oxybenzohydrazide and salicylohydrazide.

Other commercially available latent hardeners from Ajinomoto include AMICURE MY-24, AMICURE GG-216 and AMICURE ATU CARBAMATE. In addition, NOVACURE HX-372, (commercially available from Asahi Kasei Kogyo, K.K., Japan) may also be used. See European Patent Application No. 459 614 discussed above.

The latent hardener may suitably be present in amounts of from about 5 to about 45 parts, desirably from about 1 to about 30 parts, more desirably from about 10 to about 20 parts by weight per 100 parts of the epoxy resin. It will be appreciated that the amount of latent hardener used depends on the epoxide equivalent weight of the particular epoxy resin used. The latent hardener may be prepared by industry recognised methods, or may be obtained commercially where available.

Discussion of the Solid Organic Acid Component:

Solid organic acids (also referred to as stabiliser acids for the purposes of the invention) are useful in the thermosetting resin formulation to improve viscosity stability. These solid organic acids include compounds having acid functional groups, as well as compounds which have an acidic proton or have an acid nature, for example enolisable materials. The level of acid required for the formulation depends on the pKa of the acid, particle size of acid, and the degree of reactivity in final adhesive system.

The term “aliphatic” as used in connection with the solid organic acid refers to C₁-C₄₀, suitably C₁-C₃₀ straight or branched chain alkenyl, alkyl, or alkynyl which may or may not be interrupted or substituted by one or more heteroatoms such as O, N or S.

The term “cycloaliphatic” as used herein refers to cyclised aliphatic C₃-C₃₀, suitably C₃-C₂₀ groups and includes those interrupted by one or more heteroatoms such as O, N, or S.

The term “aromatic” refers to C₃-C₄₀ suitably C₃-C₃₀ aromatic groups including heterocyclic aromatic groups containing one or more of the heteroatoms, O, N, or S, and fused ring systems containing one or more of these aromatic groups fused together.

The term “carboxylic acid” includes acids having one or more carboxylic groups, and if two or more are present, one or more may be optionally esterified, the ester group suitably comprising a C₁-C₁₀ alkyl group suitably a C₁-C₄ alkyl group.

The term “quinone” includes compounds having one or more quinone groups and the terms aliphatic, cycloaliphatic and aromatic when used to describe quinones are used to refer to quinones to which aliphatic, cycloaliphatic and aromatic groups or combinations of these groups are attached by direct bonding or ring fusion.

The term “phenol” includes compounds having one or more phenolic groups and the terms aliphatic, cycloaliphatic and aromatic when used to describe phenols is used to refer to phenols to which aliphatic, cycloaliphatic and aromatic groups or combinations of these groups are attached by direct bonding or ring fusion.

The term “enolisable” includes compounds having one or more enolisable functional groups.

The term “derivatives” refers to substitutions at one ore more positions (including directly on a heteroatom) with one or more of the following:

C₁-C₂₀ alkoxy, C₁-C₂₀ alkyl, C₂-C₂₀ alkenyl, a carbonyl group, a thiocarbonyl group such as a —C═S group, a carboxylic group, a C₁-C₄ alkyl group further containing up to three N atoms, phenyl, C₁-C₄ alkylphenyl, or C₂-C₄ alkenylphenyl; OR, NR, SR, or SSR, where R is phenyl, an aliphatic, cycloaliphatic or aromatic group, each of which may be optionally further substituted in any position with one or more, of C₁-C₄ alkyl, OH, halogen (F, Br, Cl, or I), phenyl, a C₁-C₄ alkylphenyl, a C₂-C₄ alkenylphenyl, or OR, where R is phenyl, a carboxylic group, carbonyl, or an aromatic group and R is optionally substituted with C₁-C₄ alkyl, OH, or halogen; or nitro, nitrile, or halogen.

Examples of useful solid organic acids are phenols, quinones, carboxylic acids and enolisable materials. An example of an enolisable material is barbituric acid. The term “acid” includes polymeric acids including polycarboxylic acids and polyphenols.

The solid organic acid should be substantially insoluble in the thermosetting resin formulation at temperatures in the range of about 5° C. to about 35° C., such as about 15° C. to about 30° C.

The solid organic acid should be present in an amount of about 0.1 to 25 parts by weight per 100 parts of the thermosetting resin in the thermosetting resin formulation.

The solid organic acid should have a degree of insolubility such that it can act as a reservoir permitting only sufficient acid to solubilise thereby neutralising any soluble curative and/or a reaction product of the thiol-capped adduct and the curative. The solid organic acid which is substantially insoluble, remains so in effective amounts at temperatures below the elevated activation temperatures necessary to initiate cure of the composition. The temperatures below the activation temperature referred to include temperatures at or about room temperature. In other words, an amount of the solid organic acid remains in the solid form, the amount being effective to stabilise the composition. Thus cure initiating species present in the composition are neutralised by the solubilised acid, on a continuing basis. Of course, depending on the particular acid and hardener the stabilisation time may vary. Those skilled in the art will readily understand how to vary that time as desired by making appropriate choices of the particular components and using suitable amounts thereof.

The solid organic acids should have a pKa less than the pKa of the thiol-capped adduct. Typically, the thiol-capped adducts have pKas within the range of about 8-12. Desirable acids are those having a pKa less than or equal to about 12.0, desirably less than or equal to about 10.0, and often less than or equal to about 9.0, such as less than or equal to about 7.5. Where a combination of two or more solid organic acids is used the pKa of the combination should be less than or equal to about 12.0. Ordinarily, at least one of the acids in the solid organic acid component has a pKa less than that of the thiol-capped adduct, i.e. less than or equal to about 12.0, and suitably less than or equal to about 10.0 and often less than or equal to about 9.0 such as less than or equal to about 7.5.

When present, the solid organic acid may react preferentially with the soluble latent hardener until the acid concentration has been exhausted, at which time the latent hardener may react with the thiol-capped adduct in the thermosetting resin formulation to commence cure of the composition. The solid organic acid component remains substantially insoluble in the composition so that solid organic acid is present in an amount effective to stabilise the rheological properties of the composition. Some rheological stabilisation may be imparted by the neutralisation of the soluble latent hardener by the solid organic acid.

The solid organic acid desirably has a mean particle size in the range about 0.1 to about 500 microns suitably about 5 to about 100 microns, and desirably about 10 to about 50 microns.

The solid organic acid may be selected from carboxylic acids of the general formula: R₁CO₂H, where R₁ is trans-CH═CHCO₂H, —CH═CHCO₂R [where R is CH₃], —CH₂C(OR′)(CO₂R″)CH₂CO₂R′″ [where is H, C₁-C₁₀alkyl, or Ar; R″ is H, C₁-C₁₀alkyl, or Ar; R′″ is H, C₁-C₁₀alkyl, or Ar], C₁₁-C₁₈ alkyl, —(CH₂)ₙCO₂H[n is 1-9],

—(CHR)ₙCO₂H [R is H or OH, n is 1 or 2], —CH(OR′)R″ [R′ is H, alkyl, R″═C₁-C₁₀ alkyl, or Ph], —CH═CH—Ar, or

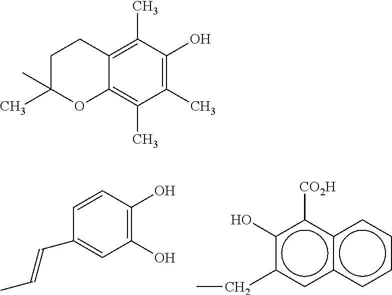

Other suitable solid organic acids are benzoic acids of the general formula:

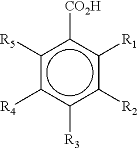

where R₁ is H, alkyl, haloalkyl such as CX₃ [where X is F, Cl, Br, or I], alkenyl, OH, OR [where R is alkyl, Ph, Bn, or Ar],

—S—S—Ar—CO₂H, —S—S—Ar, —SR [where R is H, alkyl, haloalkyl, Ph, Bn, or Ar], Ph, Bn, Ar, CO₂R [where R is H, alkyl, Ph, Bn, or Ar], C(═O)R [where R is H, alkyl, Ph, Bn, or Ar], or NO₂; R₂ is H, alkyl, haloalkyl such as CX₃ [where X is F, Cl, Br, or I], alkenyl, Ph, Bn, Ar, OH, OR [where R is alkyl, Ph, Bn, or Ar],

—CH₂Ar, NO₂, C(═O)R [where R is C₁-C₁₀ alkyl, Ph, Bn, or Ar], CHO, CO₂R [where R is H, alkyl, haloalkyl, Ph, Bn, or Ar], or

R₃ is H, alkyl, haloalkyl such as CX₃ [where X is F, Cl, Br, or I], alkenyl, OH, OR [where R is alkyl, Ph, Bn, or Ar], Ph, Bn, Ar, alkyl, CHO, C(═O)R [where R is alkyl, Ph, Bn, or Ar], CO₂R [where R is H, alkyl, Ph, Bn, or Ar] or NO₂; R₄ is H, alkyl, haloalkyl such as CX₃ [where X is F, Cl, Br, or I], alkenyl, OH, OR [where R is alkyl, Ph, Bn, or Ar], NO₂, C(═O)R [where R is alkyl, Ph, Bn, or Ar], CHO, CO₂R [where R is H, alkyl, Ph, Bn, or Ar], Ph, Bn, or Ar; R₅ is H, alkyl, haloalkyl such as CX₃ [where X is F, Cl, Br, or I], alkenyl, OH, OR [where R is alkyl, Ph, Bn, or Ar], Ph, Bn, Ar, CHO, C(═O)R [where R is alkyl, Ph, Bn, or Ar], CO₂R [where R is H, alkyl, Ph, Bn, or Ar], or NO₂.

Quinones of the general formula below are also suitable for use herein.

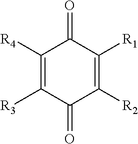

where R₁, R₂, R₃ and R₄ are independently H, alkyl, haloalkyl, alkenyl, OR[R is H, alkyl, Ar, Ph, or Bn] CN, Ph, or Ar.

Phenols of the general formula below are also suitable for use herein.

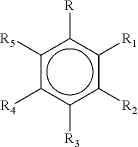

where R is H or OH; R₁ is H, alkyl, haloalkyl such as CX₃ [where X is F, Br, Cl, or I], alkenyl, Cl, F, Br, I, CN, OH, OR [where R is alkyl, Ph, Bn, or Ar], NO₂, C(═O)R [where R is alkyl, Ph, Bn, or Ar], CHO, CO₂R [where R is H, alkyl, Ph, Bn, or Ar], or PhOH; R₂ is H, alkyl, haloalkyl, alkenyl, OH, OR [where R is alkyl, Ph, Bn, or Ar], Ph, Bn, —CH₂Ar, CN, F, Cl, Br, or I;

R₃ is H, alkyl, haloalkyl such as CX₃ [where X is F, Br, Cl, or I], alkenyl, NO₂, C(═O)R [where R is alkyl, Ph, Bn, or Ar], CHO, CO₂R [where R is alkyl, Ph, Bn, or Ar], OH, OR [where R is alkyl, Ph, Bn, or Ar], Ar, Bn, Ph, C(R)₂PhOH [where R is Me or H], C(R)₂Ar [where R is Me or H] or

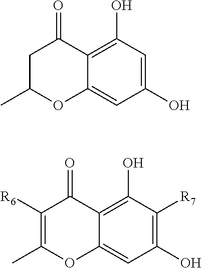

where R₆ and R₇ are independently H, alkyl, haloalkyl, alkenyl, OH, or OR [where R is alkyl, Ph, Bn, or Ar]; R₄ is H, alkyl, haloalkyl, alkenyl, OH, OR [where R is alkyl, Ph, Bn, or Ar], F, Cl, Br, I, CN, Ph, Bn, or —CH₂Ar; R₅ is H, alkyl, haloalkyl such as CX₃ [where X is F, Br, Cl, or I], alkenyl, F, Cl, Br, I, CN, OH, OR [R is alkyl, Ph, Bn, or Ar], NO₂, C(═O)R [where R is alkyl, Ph, Bn, or Ar], CHO, CO₂ R [where R is H, alkyl, Ph, Bn, or Ar], or PhOH, provided that a compound of general Formula IV is chosen to have at least one phenolic group present.

Enolisable materials such as those compounds of the general formula below are also suitable for use herein.

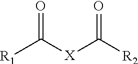

where R₁ or R₂ are NR′C(═O)NR″R′″ [where R′ is H, alkyl, Ph, or Ar; R″ is H, alkyl, Ph, or Ar; and R′″ is H, alkyl, Ph, or Ar], or OR [where R is H, alkyl, Ph, or Ar]; X is (CH₂)ₙ, C(R)₂ [where R is alkyl, Ph, Ar, or CN], O, S, NR [where R is H, alkyl, Ph, or Ar], and n is 1-10.

The enolisable material of the preceding paragraph may be selected from compounds of the general formula below:

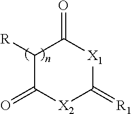

where
(a) X₁═X₂═NH, R═H, R₁═O, n=1; or
(b) X₁═X₂═NH, R₁═O, n is zero so that the cyclic structure has a five membered ring; or
(c) X₁═X₂═O, R═H, R₁=(CH₃)₂, n=1; or
(d) X₁═X₂═O, R=Ph, R₁═(CH₃)₂, n=1.

In the general formulae above for the solid organic acids, Ar represents substituted phenyl, substituted or unsubstituted bicyclic or multicyclic aromatic compounds, e.g., naphthalene, substituted naphthalene, and the like and Ph is phenyl. Bn is a substituted or unsubstituted benzyl group. Alkyl may be straight chained or branched C₁-C₂₀ alkyl, suitably C₁-C₁₀ alkyl. Haloalkyl should be interpreted as an alkyl substituted one or more times by one or more halogens. Alkenyl may be straight chain or branched C₂-C₂₀ alkenyl, suitably C₂-C₁₀ alkenyl.

The solid organic acid may for example be selected from 4-nitroguaiacol, 3,4,5-trimethoxy benzoic acid, hexachlorophene, 3,5-dinitrosalicylic acid, 4,5,7-trihydroxyflavanone, 2,2-dithiosalicylic acid, phloroglucinol, fumaric acid, 3,4-dihydroxy benzoic acid, 3,4,5-trihydroxy benzoic acid, trolox, pamoic acid, ascorbic acid, salicylic acid, citric acid, 3,4-dihydroxy cinnamic acid, 2,3-dicyanohydroquinone, barbituric acid, tetrahydroxy-p-benzoquinone, parabanic acid, phenyl boronic acid, 5-phenyl Meldrum's acid and Meldrum's acid.

Of these acids those which display a greater stabilising effect are barbituric acid, Trolox, and fumaric acid with barbituric acid displaying a better stabilising effect. A number of solid organic acids which are set out below, and for ease of discussion herein only, have been classified into four different groups.

Examples of Solid Organic Acids

| Phenolic Functional Groups | Carboxylic Functional Groups |
|---|---|
| 4-nitroguaiacol | 3,4,5-trimethoxy benzoic acid |
| hexachlorophene | 3,5-dinitrosalicylic acid |
| 4,5,7-trihydroxyflavanone | 2,2-dithiosalicylic acid |
| phloroglucinol | fumaric acid |
| | 3,4-dihydroxy benzoic acid |
| | 3,4,5-trihydroxy benzoic acid |
| | Trolox (6-hydroxy-2,5,7,8- |
| | tetramethylchroman-2 carboxylic acid) |
| | pamoic acid |
| | ascorbic acid |
| | salicylic acid |
| | citric acid |
| | 3,4-dihydroxy cinnamic acid |
| Quinone Derivatives | Enolisable Acids |
| 2,3-dicyanohydroquinone | barbituric acid |
| tetrahydroxy-p-benzoquinone | parabanic acid |
| | phenyl boronic acid |
| | 5-phenyl Meldrum's acid |
| | Meldrum's acid |

The compositions according to the invention possess improved storage stability, extended working lives and relatively short curing times at relatively low temperatures compared to known compositions. The compositions provide an increase in the stability by prolonging pot life without substantially affecting gel-times.

The rheological properties referred to include those such as improved shelf-life stability, particularly with respect to yield point maintenance over time, viscosity maintenance over time, and room temperature pot life. In particular, the solid organic acid initially enhances the yield point and stabilises the yield point of the composition over time beyond that which is observed from compositions which do not include the solid organic acids. The yield point (or yield stress) may generally be thought of as the minimum stress required to cause a material to flow. The solid organic acid stabilises both the chemical and physical properties of the epoxy resin compositions of the present invention, an effect which is quantifiable by the properties given above.

Discussion of the Thixotropy-Conferring Component:

The thixotropy-conferring component used in accordance with the present invention may often include reinforcing silicas, such as fused or fumed silicas, and may be untreated or treated so as to alter the chemical nature of their surface. Virtually any reinforcing, fused or fumed silica may be used.

Examples of such treated fumed silicas include polydimethylsiloxane-treated silicas and hexamethyldisilazane-treated silicas. Such treated silicas are commercially available, such as from Cabot Corporation under the tradename CAB-O-SIL ND-TS and Degussa Corporation under the tradename AEROSIL, such as AEROSIL R805.

Of the untreated silicas, amorphous and hydrous silicas may be used. For instance, commercially available amorphous silicas include AEROSIL 300 with an average particle size of the primary particles of about 7 nm AEROSIL 200 with an average particle size of the primary particles of about 12 nm, AEROSIL 130 with an average size of the primary particles of about 16 nm; and commercially available hydrous silicas include NIPSIL E150 with an average particle size of 4.5 nm, NIPSIL E200A with and average particle size of 2.0 nm, and NIPSIL E220A with an average particle size of 1.0 nm (manufactured by Japan Silica Kogya Inc.).

Desirable ones also have a low ion concentration and are relatively small in particle size (e.g., on the order of about 2 microns), such as the silica commercially available from Admatechs, Japan under the trade designation SO-E5. Other desirable materials for use as the thixotropy-conferring component include those constructed of, or containing aluminum oxide, silicon nitride, aluminum nitride and silica-coated aluminum nitride.

The thixotropy-conferring agent should be used in an amount within the range of to 40 parts, such as about 15-25 parts, per hundred parts of the epoxy component depending on the rheology requirements of the end use application.

The particular set of rheological properties developed for an adhesive may tend to change over time. These properties impact the shelf-life stability of the adhesive composition, and can affect the dispensability of the adhesive in its end-use applications. Many commercially available adhesives, including currently-available epoxy-based adhesives, are inherently chemically unstable and, even under manufacturer-recommended refrigerated storage conditions, can suffer from unstable rheological properties (such as yield point decreases over time). The extent of this instability often depends upon temperature. Such yield point instability can affect the dispensability of the composition over time and can result in weaker bond strengths due to changes in the dot profile.

More specifically, in the context of curable one-part epoxy resins, viscosity increases are often seen over time, with the viscosity increase often being drastic in a relatively short time period. In such case, the pot life may be considered too short for wide-range commercial applicability. Such viscosity increases are due at least in part to the onset of polymerization initiation.

Yield point decreases may also be observed to occur over time in such compositions. Such yield point decreases are particularly prevalent in those compositions whose structure has been increased through the addition of thickeners or thixotropy-conferring components.

As noted, these changes in rheological properties over time adversely impact the shelf-life stability of the adhesive composition. The epoxy resin compositions of the invention which comprise this thixotropy-conferring agent typically have yield points in the range of about 30-700 Pa, suitably 150-450 Pa, and a viscosity measured at a temperature of about 25[deg.] C. in the range of about 1-50 Pa·s, suitably 1 to 25 Pa·s desirably 1-10 Pa·s. The yield point and the viscosity are maintained substantially within these respective ranges over time.

Other Additives:

Any number of conventional additives may also be added to the epoxy resin compositions of the present invention including fillers, thixotropic imparting agents (if not already present), reactive diluents, non-reactive diluents, pigments, flexibilisers, and the like, depending on the intended end use of the composition.

### EXAMPLES

The materials used in the following non-limiting examples are referred to as follows:

“Epon 828” is a bisphenol A epoxy resin (trade name of Shell Chemical Co.)
“PN-23” —AJICURE PN-23 (trade name, product of Ajinomoto Co., Inc.)
“Karenz MT PE1” (trade name, product of Showa Denko)
“Karenz MT NR1” —(trade name, product of Showa Denko)
“Karenz MT BD1” —(trade name, product of Showa Denko)
“PM182” is 20 Wt. % jet milled barbituric acid dispersed into EPON 828 with 2 wt. % fumed silica as a thixotrope to prevent sedimentation of the acid.

The formulations according to the invention were prepared using the following procedure:

The appropriate quantity of epoxy resin(s) and the required polythiol were charged into a mixing vessel equipped with a cooling jacket, a vacuum attachment and suitable mixing blades and blended together under vacuum until a homogeneous mix was obtained. The vessel was then charged with the acid stabiliser together with any other required materials such as pigments/fillers/thixotropes/toughening agents/adhesion promoters etc. and sheared under vacuum until all materials were fully wetted in/homogenous. The batch temperature was allowed to cool to 25° C. before adding the curing agent component. The curing agent component was blended in under low shear conditions to avoid build up of excess heat and mixed under vacuum to fully deaerate until the required yield point/viscosity target specification was achieved.

The following formulations were prepared using the Karenz MT® thiols (available from Showa Denko) and compared to a control which contained the primary thiol, trimethylol propane tris(β-mercaptopropionate).

TABLE 1

| | Control | I | II | III | IV |
|---|---|---|---|---|---|
| Epon 828 | 100 | 100 | 100 | 100 | 100 |
| 3-277 | 75 | — | — | — | — |
| Karenz MT | — | 72 | 72 | — | — |
| PE1 | | | | | |
| Karenz MT | — | — | — | 100 | 100 |
| NR1 | | | | | |
| Aerosil R202 | 7.0 | 7.0 | 7.0 | 7.0 | 7.0 |
| PM 182 | 1.5 | 0.75 | 1.5 | 0.75 | 1.5 |
| Ajicure PN 23 | 25 | 25 | 25 | 25 | 25 |

Each formulation was compounded and tested for reactivity by dynamic DSC and isothermal @ 100° C.

TABLE 2

| | Control | 1 | II | III | IV |
|---|---|---|---|---|---|
| T onset (° C.) | 63 | 69 | 75 | 62 | 72 |
| Peak onset (° C.) | 80 | 77 | 85 | 74 | 88 |
| T peak (° C.) | 92 | 85 | 101 | 85 | 97 |
| ΔH (^{j}/g) | 351 | 312 | 321 | 304 | 300 |
| % | | | | | |
| Conversion | | | | | |
| @100° C. | | | | | |
| 1.3 minute | 95% | | | | |
| 1.4 minute | — | 95% | 95% | 95% | 95% |

From the DSC data above it can be seen that the formulations have similar reactivity in terms of T peak temperatures. The main difference lies in the higher T onset temperatures (formulations II and IV) which should help to improve the thermal stability. In terms of the isothermal data, all formulations showed very fast conversion within minutes at 100° C. as expected.
Tensile strength was also studied using grit blasted mild steel lap shears cured for 30 minutes @ 100° C. Glass transition temperature was also recorded using DMA.

TABLE 3

| Tensile | | | | | |
|---|---|---|---|---|---|
| Shear N/MM² | Control | I | II | III | IV |
| GBMS cured | 26.29 | 28.40 | 25.83 | 26.29 | 30.62 |
| 30 mins @ | | | | | |
| 100° | | | | | |
| Tg(° C.) | 49.7 | 63.2 | 60.8 | 57.8 | 57.9 |

Excellent lap shear strengths and adhesion were achieved in all cases. There was also an improvement in the Tg value.
A 40° C. accelerated age test was conducted to determine if the secondary thiol resins offer any improvement in terms of thermal stability. Samples were withdrawn from 40° C. ageing periodically and their relative viscosity recorded on the Haake cone and plate rheometer.

TABLE 4

| Time @ 40° C. | Control | | 1 | | II | | III | | IV | |
|---|---|---|---|---|---|---|---|---|---|---|
| Initial | 2.897 | Pa s | 8.344 | Pa s | 8.177 | Pa s | 17.26 | Pa s | 18.2 | Pa s |

| | | | | | | | | | |
|---|---|---|---|---|---|---|---|---|---|
| 4 days | Set Up | 7.467 | Pa s | 8.05 | Pa s | 21.17 | Pa s | 20.17 | Pa s |
| 7 days | — | 8.275 | Pa s | 8.42 | Pa s | 24.2 | Pa s | 22.76 | Pa s |
| 11 days | — | 9.03 | Pa s | 8.80 | Pa s | 24.52 | Pa s | 22.65 | Pa s |
| 14 days | — | 13.14 | Pa s | 9.19 | Pa s | 27.09 | Pa s | 24.14 | Pa s |

| | | | | | |
|---|---|---|---|---|---|
| 35 days | — | set up | na | set up | na |
| 39 days | — | — | set up | — | 30.92 |

The initial viscosity results indicate that the secondary thiol resins are indeed significantly more stable compared to the original formulation. After 11 days at 40° C. there is practically little or no increase in viscosity for those formulations containing the Karenz MT® resins whereas the control had set up (cured) after only 4 days at 40° C. After approximately 35 days ageing at 40° C. formulations I and III had set up whereas formulation II had set up after 39 days. Formulation IV was the most stable and was still mobile after 39 days ageing.

The words “comprises/comprising” and the words “having/including” when used herein with reference to the present invention are used to specify the presence of stated features, integers, steps or components but does not preclude the presence or addition of one or more other features, integers, steps, components or groups thereof.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable sub-combination.

1. A curable one-part epoxy resin composition, comprising:
(a) an epoxy component comprising at least one epoxy compound which has two or more groups per molecule;
(b) a latent hardener component;
(c) a thixotropy-conferrring component;
(d) a polythiol component comprising a polythiol having at least one secondary or tertiary thiol group per molecule; and
(e) a stabilising component comprising a solid organic acid.

2. The composition according to claim 1 wherein the polythiol comprises at least two secondary thiol groups.

3. The composition according to claim 1, wherein the polythiol comprises at least three secondary thiol groups.

4. The composition according to claim 1, wherein the polythiol comprises at least four secondary thiol groups.

5. The composition according to claim 1 wherein the polythiol comprises at least two tertiary thiol groups.

6. The composition according to claim 1 wherein the polythiol is selected from the group consisting of

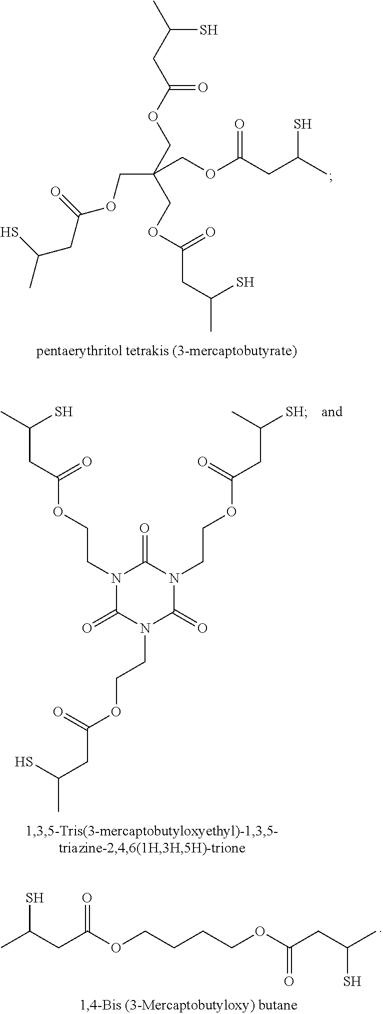

7. The composition according to claim 1 suitable for use as an adhesive to mount electronic components.

8. The composition according to claim 1, comprising:
(a) about 100 parts of an epoxy component comprising at least one epoxy compound;
(b) about 5 to 45 parts of a latent hardener component;
(c) about 5 to 40 parts of a thixotropy-conferring component; and
(d) about 20 to 200 parts of a secondary polythiol; and
(e) about 0.1 to 25 parts of a solid organic acid.

9. The composition according to claim 1 comprising:
(a) about 100 parts of an epoxy component comprising at least one epoxy compound;
(b) about 10-30 parts of a latent hardener component;
(c) about 5-15 parts of a thixotropy-conferring component; and
(d) about 20 to 200 parts of a secondary polythiol; and
(e) about 0.1 to 25 parts of a solid organic acid.

10. The composition according to claim 1 wherein the Tₒₙₛₑₜ is in the range of 40-120° C., more particularly in range 50-100° C.

11. The composition according to claim 1 wherein the composition has a viscosity in the range of 0.5-100 Pa·s.

12. The composition according to claim 1 wherein the composition has a yield point in the range 30-1000 Pa.

13. A process for preparing a curable one-part epoxy resin composition, comprising the steps of:
combining initially (i) an epoxy component and a polythiol having at least one secondary or tertiary thiol group per molecule;
(ii) adding a solid organic acid and one or more excipients and shearing under vacuum;
(iii) allowing said mixture to cool; and
(iv) adding a latent hardener and mixing under vacuum for a time sufficient to form the curable one-part epoxy composition.

14. A method of using a composition according to claim 1, the method comprising the steps of: dispensing onto an appropriate location on a carrier substrate a sufficient amount of the composition, positioning over the location bearing the composition an electronic component, mating the electronic component with the carrier substrate, and exposing the mated electronic component/carrier substrate assembly to conditions favourable to effect cure of the composition.

15. An electronic device comprising a semiconductor device and a circuit board to which said semiconductor device is electrically connected, assembled using an epoxy resin composition according to claim 1 to mount the semiconductor to the circuit board.

16. A method of underfilling a space between an electronic component and a carrier substrate the electronic component being mounted on the carrier substrate, comprising the step of dispensing an amount of a composition according to claim 1 into the space between the electronic component and the carrier substrate, and exposing the epoxy resin composition to conditions which effect cure.
